(19) United States
(12) Patent Application Publication
(10) Pub. No.: US 2024/0387748 A1
(43) Pub. Date: Nov. 21, 2024

(54) SEMICONDUCTOR STRUCTURES AND METHODS FOR FORMING THE SAME

(71) Applicant: Winbond Electronics Corp., Taichung City (TW)

(72) Inventors: Ying-Chang WEI, Taichung City (TW); Chao-Lung WANG, Taichung City (TW); Jung-Ho CHANG, Hsinchu City (TW); Hsiu-Han LIAO, Hsinchu City (TW)

(21) Appl. No.: 18/485,520

(22) Filed: Oct. 12, 2023

(30) Foreign Application Priority Data
May 17, 2023 (TW) 112118315

(51) Int. Cl. H01L 29/788; H01L 21/28; H01L 21/762

(52) U.S. Cl. CPC H01L 29/788; H01L 21/76224; H01L 29/40114

(57) ABSTRACT

A semiconductor structure is provided. The semiconductor structure includes a substrate; a dielectric layer on the substrate; isolation structures extending through the dielectric layer into the substrate; and a floating gate on the dielectric layer and between the isolation structures, wherein the floating gate includes a first portion directly on the dielectric layer; and second portions on the sidewalls of the first portion.

### CROSS-REFERENCE TO RELATED APPLICATIONS

The present application claims priority of Taiwan Application No. 112118315, filed on May 17, 2023, which is incorporated by reference herein in its entirety.

### BACKGROUND

### Technical Field

The present disclosure relates to semiconductor structures and method for forming the same, and more particularly to memory structures and method for forming the same.

### Description of the Related Art

A flash memory has the advantages of high density, low cost, and being rewritable and electrically erasable. In order to increase the element density in the flash memory and improve its performance, the current technology used to manufacture flash memory continues to strive toward scaling down the devices. However, as flash memory is scaled down, the pitch between adjacent elements becomes smaller. When a floating gate is formed with a filling material, the possibility of forming voids or seams in the floating gate increases, thereby degrading the performance, yield and reliability of the memory device.

### SUMMARY

The present disclosure provides a method for forming a semiconductor structure, including: providing a substrate; forming a dielectric layer on the substrate; forming a first conductor layer on the dielectric layer; forming isolation structures on the substrate, wherein the isolation structures extend through the first conductor layer and the dielectric layer into the substrate; removing a portion of the isolation structures; conformally forming a second conductor layer on the first conductor layer and the isolation structures; and removing horizontal portions of the second conductor layer to form a floating gate, wherein the floating gate includes vertical portions of the first conductor layer and the second conductor layer.

The present disclosure provides a semiconductor structure, including a substrate; a dielectric layer on the substrate; isolation structures extending through the dielectric layer into the substrate; and a floating gate on the dielectric layer and between the isolation structures, wherein the floating gate includes: a first portion directly on the dielectric layer; and second portions on sidewalls of the first portion.

### BRIEF DESCRIPTION OF THE DRAWINGS

FIG. 1 illustrates a flowchart of a method for forming a semiconductor structure, according to some embodiments of the present disclosure.

FIGS. 2-12 are cross-sectional views of the semiconductor structure at various stages of the method shown in FIG. 1, according to some embodiments of the present disclosure.

### DETAILED DESCRIPTION

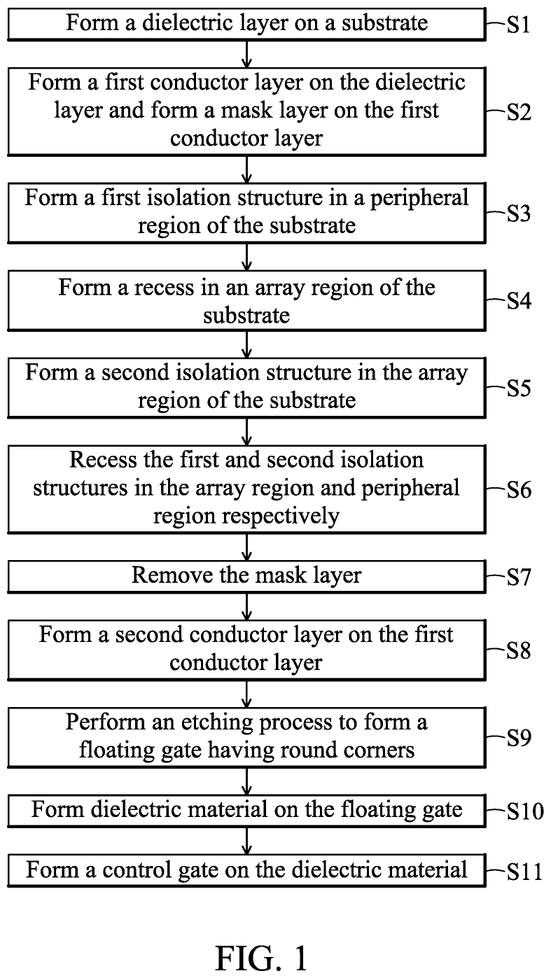

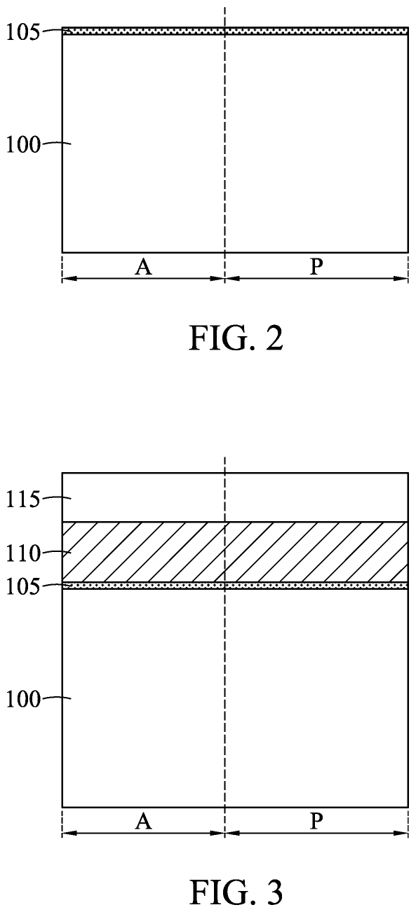

Referring to FIGS. 1 and 2, in step S1, a substrate 100 is provided. The substrate 100 may be, for example, an element semiconductor substrate, a compound semiconductor substrate, a silicon-on-insulator (SOI) substrate, another suitable semiconductor material, or a combination thereof. In some embodiments, the substrate 100 may be doped with P-type dopants, such as boron, or N-type dopants, such as phosphorus or arsenic. In some embodiments, the substrate 100 may include an array region A and a peripheral region P. It should be understood that the array area A and the peripheral area P shown in the figures are embodiments of a portion of each region, rather than the region where the two are connected.

In step S1, a dielectric layer 105 is formed on the substrate 100. In some embodiments, the dielectric layer 105 formed of silicon oxide may be formed by performing an oxidation process on the substrate 100 (e.g., a silicon substrate). In some embodiments, the oxidation process may include a thermal oxidation process, a radical oxidation process, another suitable process, or a combination thereof.

Referring to FIGS. 1 and 3, in step S2, a first conductor layer 110 is formed on the dielectric layer 105. The first conductor layer 110 may be, for example, polysilicon. In some embodiments, the first conductor layer 110 may be formed through a deposition process. The deposition process may include a chemical vapor deposition (CVD) process, an atomic layer deposition (ALD) process, a plasma-enhanced chemical vapor deposition (PECVD) process, another suitable deposition process, or a combination thereof.

In step S2, a mask layer 115 is formed on the first conductor layer 110. The mask layer 115 may include oxide, nitride, or a combination thereof. It should be understood that although the mask layer 115 is shown as a single layer in FIG. 3, the mask layer 115 may be a stack of multiple layers. In some embodiments, the mask layer 115 may be formed through a deposition process, such as a physical vapor deposition (PVD) process, a chemical vapor deposition process, a plasma-enhanced chemical vapor deposition process, an atomic layer deposition process, or a combination thereof.

The mask layer 115 may be used to pattern underlying layers. The patterning process may include a lithography process and an etching process. The lithography process may include photoresist coating (e.g., spin coating), soft bake, mask alignment, exposure, post-exposure bake, photoresist development, cleaning, drying (e.g., hard bake), another suitable process, or a combination thereof. In some embodiments, the lithography process may be replaced by electron beam writing or ion beam writing. The etching process may include dry etching, wet etching, or a combination thereof. In some embodiments, dry etching may include plasma etching, plasma-free gas etching, sputter etching, ion milling, reactive ion etching (RIE), neutral beam etching (NBE), inductive coupled plasma etch, another suitable etching process, or a combination thereof.

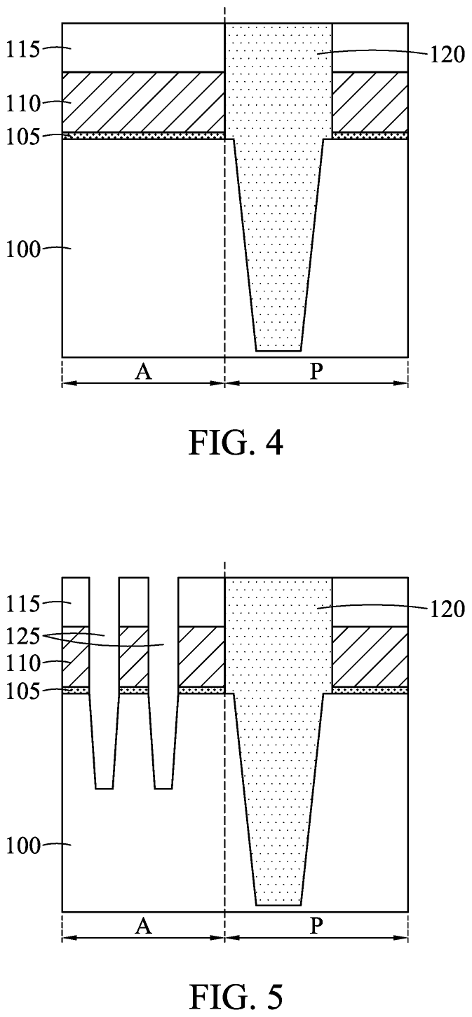

Referring to FIGS. 1 and 4, in step S3, an isolation structure 120 is formed in the peripheral region P of the substrate 100. In some embodiments, the isolation structure 120 may be a single-layer structure formed of a single material or a multi-layer structure formed of multiple different materials. In some embodiments, the isolation structure 120 may include oxide, nitride, oxynitride, carbide, another suitable material, or combinations thereof.

In some embodiments, a photoresist layer (not shown) may be formed on the mask layer 115 through spin coating, and the photoresist layer is irradiated with radiation (for example, ultraviolet light) through a photomask such that the irradiated regions of the photoresist form regions that are soluble in a develop solution. Subsequently, the photoresist layer is developed to remove the irradiated regions to define openings, and portions of the mask layer 115 not covered by the photoresist layer are removed through the openings until the first conductor layer 110 is exposed. Subsequently, the photoresist layer is removed and an etching process is performed through the openings to form recesses extending into the substrate 100. After that, an isolation material is formed in the recesses through a deposition process, and a planarization process is performed to remove excess isolation material on the top surface of the mask layer 115 so that the top surface of the mask layer 115 is coplanar with the top surface of the isolation material that is used to form isolation structure 120.

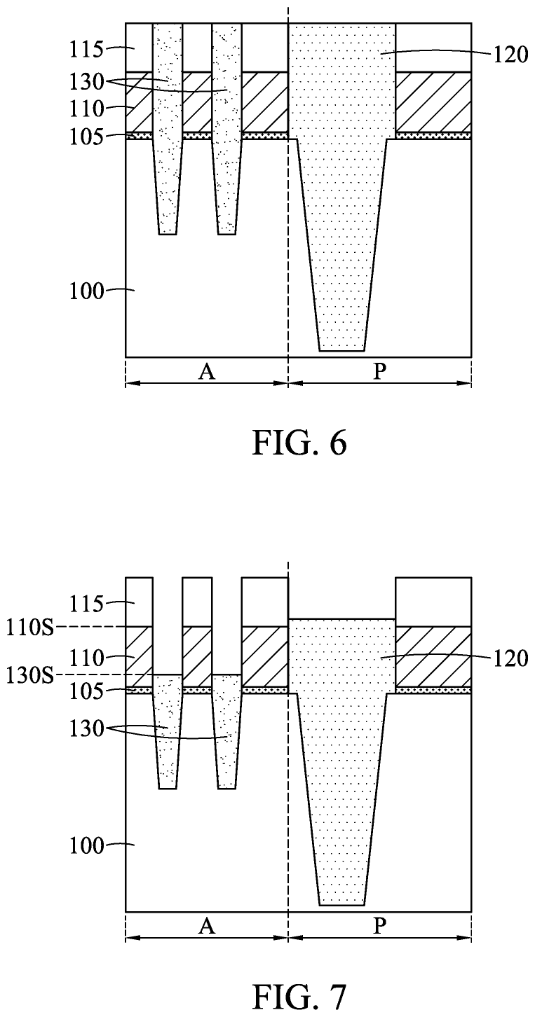

Referring to FIGS. 1, 5 and 6, in steps S4 and S5, recesses 125 are formed in the array region A of the substrate 100, and isolation structures 130 are formed. In some embodiments, the formation of the recesses 125 and the isolation structure 130 is similar to the formation of the recess and the isolation structure 120 described above. Thus, it is not repeated herein. In some embodiments, the isolation structure 120 is formed in the peripheral region P, and then the isolation structures 130 are formed in the array region A. In other embodiments, the isolation structure 120 in the peripheral region P and the isolation structures 130 in the array region A may be formed simultaneously in the same step. It should be noted that, in some embodiments of the present disclosure, the first conductor layer 110 (which will be a portion of a floating gate described later) is formed on the substrate 100, and then the first conductor layer 110 is patterned in the process of forming the recesses 125 (the isolation structures 130 to be formed therein). That is, the patterns of the isolation structures 130 and the pattern of the floating gate are completed in the same patterning process. In this way, since the first conductor layer 110 is deposited on a flat surface, the formation of the floating gate with voids or seams can be prevented, and the problem of thinning the dielectric layer under the floating gate can be avoided, thereby improving performance and reliability of the memory structure.

In particular, in a conventional method of forming a memory structure, isolation structures are formed, and then recesses between the isolation structures are filled with semiconductor material to form a floating gate. Due to continuous scale down of elements, the possibility of forming void or seams increases when filling the recesses between the isolation structures, resulting in the formation of the floating gate with voids or seams. When an inter-gate dielectric layer and a control gate are subsequently formed on the floating gate with voids or seams, the dielectric layer filled in the voids or seams will increase the voltage loss in this region from the control gate to the floating gate, thereby reducing the operating speed of the memory device. Further, the dielectric layer filled in the voids or seams will also lead to a wider distribution of the threshold voltage of the memory device, thereby reducing the reliability of the memory device. Furthermore, during a subsequent patterning process of the control gate, the voids or seams in the floating gate may be exposed on sidewalls of the floating gate. The exposed voids or seams may cause damage or thinning of the dielectric layer under the floating gate during the patterning process such that charges stored in the floating gate will escape outward through the damaged portion, thereby reducing data retention of the memory device and even causing the memory device to fail.

Referring to FIGS. 1 and 7, in step S6, the isolation structure 120 and the isolation structures 130 are etched back. In some embodiments, a dry etching process may be performed to etch back the isolation structure 120 and the isolation structures 130. After the etching process, the top surfaces 130S of the isolation structures 130 are lower than the top surface 110S of the first conductor layer 110.

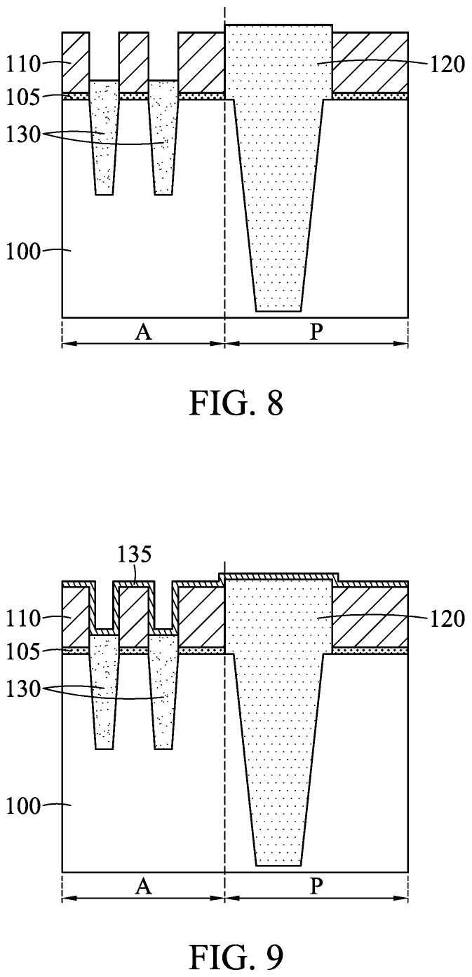

Referring to FIGS. 1 and 8, in step S7, the mask layer 115 is removed. In some embodiments, the removal of the mask layer 115 may include a strip process, an ash process, another suitable process, or a combination thereof.

Referring to FIGS. 1 and 9, in step S8, a second conductor layer 135 is conformally formed on the first conductor layer 110, the isolation structures 130 and the isolation structure 120. In some embodiments, the second conductor layer 135 may include the same material as the first conductor layer 110. The second conductor layer 135 and the first conductor layer 110 may include polysilicon. In some embodiments, the second conductor layer 135 may be formed through a deposition process. The deposition process may include a chemical vapor deposition process, an atomic layer deposition process, a plasma-enhanced chemical vapor deposition process, another suitable deposition process, or a combination thereof.

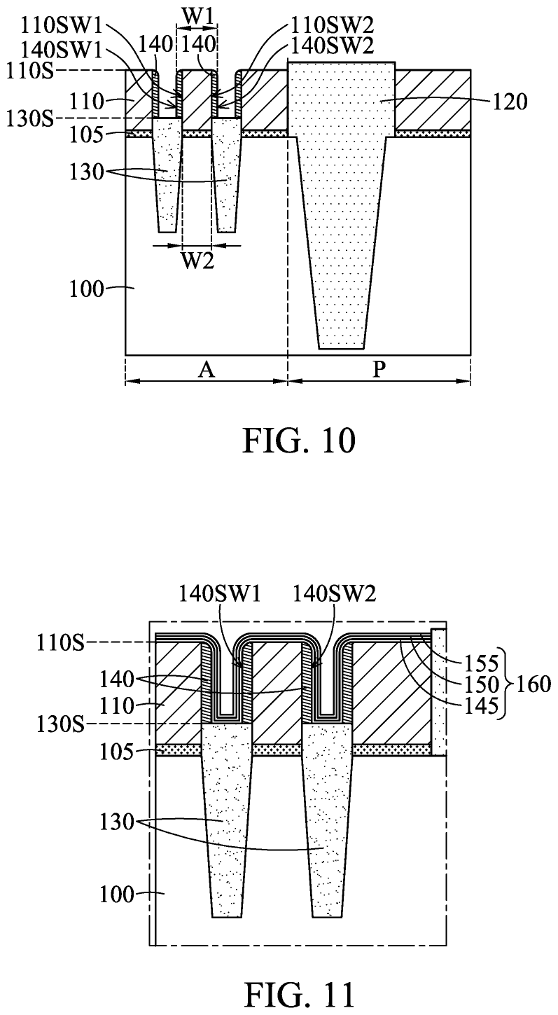

Referring to FIGS. 1 and 10, in step S9, an etching process (for example, a reactive ion etching process) is performed to remove horizontal portions of the second conductor layer 135 on the first conductor layer 110, the isolation structures 130 and the isolation structure 120 to form a floating gate. As shown in FIG. 10, after the etching process, vertical portions 140 of the second conductor layer 135 remain on the sidewalls 110SW1 and 110SW2 of the first conductor layer 110, while the top surface 110S of the first conductor layer 110 and the top surfaces 130S of the isolation structures 130 are exposed. In this way, the floating gate includes a first portion 110 (i.e., the first conductor layer 110 directly on the dielectric layer 105) and second portions 140 (i.e., remaining vertical portions 140 of the second conductor layer 135 on the sidewalls 110SW1 and 110SW2 of the first conductor layer 110).

As shown in FIG. 10, the top surface 110S of the floating gate is higher than the top surfaces 130S of the isolation structures 130; the width W1 of the top portion of the floating gate is greater than the width W2 of the bottom portion of the floating gate; the first portion 110 is in direct contact with the sidewalls of the isolation structures 130; and the bottom surfaces of the second portions 140 of the floating gate directly and completely contacts the top surfaces 130S of the isolation structures 130. It should be understood that, in FIG. 10, in order to clearly indicate that the second portions 140 are located on the sidewalls 110SW1 and 110SW2 of the first portion 110, there are an obvious boundaries between the first portion 110 and the second portions 140. However, in embodiments where the first conductor layer 110 and the second conductor layer 135 include the same material (e.g., polysilicon), there are no obvious boundaries between the first portion 110 and the second portions 140.

Compared with the floating gate without the second portions 140, the volume of the floating gate with the second portions 140 is increased. In addition, since the etching process is performed to remove the horizontal portions of the second conductor layer 135, the top of the vertical second portions 140 has rounded corners. The floating gate on the dielectric layer 105 has increased volume and rounded corners such that a contact surface area of the floating gate with a dielectric material (dielectric material 160 described later) to be formed thereon is increased such that a gate coupling ratio (GCR) can be enhanced. In some embodiments, the gate coupling ratio can be shown as:

$$\frac{{C}_{ONO}}{{C}_{TUN} + {C}_{ONO}}$$

where C_{ONO} represents the capacitance of the dielectric material above the floating gate; and C_{TUN} represents the capacitance of the dielectric layer (which may also be referred to as a tunneling oxide layer (TOX)) below the floating gate. Therefore, in order to obtain a high gate coupling ratio, C_{ONO} needs to have a high value relative to C_{TUN}. As mentioned above, the floating gate provided by embodiments of the present disclosure has increased volume and rounded corners such that the contact surface area with the dielectric material formed thereon is increased. Therefore, C_{ONO} is increased, thereby obtaining a higher gate coupling ratio.

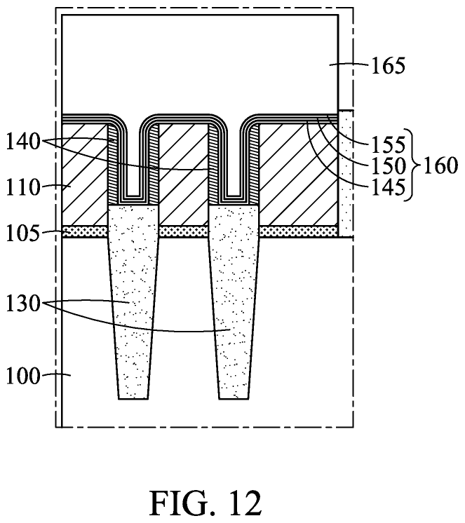

Referring to FIGS. 1 and 11, in step S10, a dielectric material 160 is formed along the sidewalls 140SW1 and 140SW2 and the top surface 110S of the floating gate and along the top surfaces of the isolation structures 130. For simplicity, FIGS. 11 and 12 only illustrate a portion of the array region. As shown in FIG. 11, the dielectric material 160 includes a first dielectric layer 145, a second dielectric layer 150, and a third dielectric layer 155 deposited sequentially from bottom to top. In some embodiments, the dielectric material 160 is a multi-layer structure. The first dielectric layer 145 and the third dielectric layer 155 may include the same material (for example, silicon oxide), and the second dielectric layer 150 may be, for example, silicon nitride. In some embodiments, the dielectric material 160 is a single-layer structure.

Referring to FIG. 11, since the floating gate has rounded corners, the width at the top of the recess between the adjacent floating gates (for example, the width of the recess at the top surface 110S of the first portion 110) is larger than the width at the bottom of the recess (for example, the width of the recess at the top surfaces 130S of the isolation structures 130). Therefore, when depositing material in the recess to form the dielectric material 160, the possibility of forming voids or seams can be reduced, thereby improving the reliability of the memory structure.

Referring to FIGS. 1 and 12, in step S11, a control gate 165 is formed on the dielectric material 160. In some embodiments, the control gate 165 may be formed through a deposition process. Since the dielectric material 160 is conformally formed on the floating gate, the dielectric material 160 also has rounded corners. Therefore, when depositing material on the dielectric material 160 to form the control gate 165, the possibility of forming voids or seams can be reduced, thereby improving the reliability of the memory structure.

It should be understood that after the control gate 165 is formed, other conventional processes may be performed according to actual requirements to complete the memory device. Other known manufacturing processes will not be repeated herein.

To sum up, some embodiments of the present disclosure provide memory structures and methods for forming the same. The floating gate has increased volume and rounded corners such that the contact surface area between the floating gate and the dielectric material thereon is increased, resulting in the increase of the gate coupling ratio (GCR). In addition, due to the rounded corners of the floating gates, the recess with the width at the top greater than the width at the bottom is formed between two adjacent floating gates, making it easier to form the control gate in the recess. Therefore, the possibility of forming voids or seams in the control gate can be reduced, thereby improving the performance and reliability of the memory structure.

The foregoing has outlined features of several embodiments such that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A method for forming a semiconductor structure, comprising:
providing a substrate;
forming a dielectric layer on the substrate;
forming a first conductor layer on the dielectric layer;
forming isolation structures on the substrate, wherein the isolation structures extend through the first conductor layer and the dielectric layer into the substrate;
removing a portion of the isolation structures;
conformally forming a second conductor layer on the first conductor layer and the isolation structures; and
removing horizontal portions of the second conductor layer to form a floating gate, wherein the floating gate comprises vertical portions of the first conductor layer and the second conductor layer.

2. The method for forming the semiconductor structure as claimed in claim 1, wherein removing the horizontal portions of the second conductor layer comprises performing an etching process on the second conductor layer such that the vertical portions of the second conductor layer remain on sidewalls of the first conductor layer and expose a top surface of the first conductor layer and top surfaces of the isolation structures.

3. The method for forming the semiconductor structure as claimed in claim 1, wherein removing the portion of the isolation structures comprises performing an etching process on the isolation structures such that top surfaces of the isolation structures are lower than a top surface of the first conductor layer.

4. The method for forming the semiconductor structure as claimed in claim 1, wherein the floating gate comprises rounded corners.

5. The method for forming the semiconductor structure as claimed in claim 1, wherein bottom surfaces of the vertical portions of the second conductor layer are in direct contact with top surfaces of the isolation structures.

6. The method for forming the semiconductor structure as claimed in claim 1, wherein a width of a top portion of the floating gate is greater than a width of a bottom portion of the floating gate.

7. The method for forming the semiconductor structure as claimed in claim 1, wherein forming the isolation structures comprises:
providing a mask layer as an etch mask and performing an etching process through the etch mask to form recesses, wherein the recesses extend from a top surface of the mask layer through the first conductor layer and the dielectric layer into the substrate;
filling the recesses with an isolation material; and
performing a planarization process to make a top surface of the isolation material coplanar with the top surface of the mask layer.

8. The method for forming the semiconductor structure as claimed in claim 1, wherein the first conductor layer and the second conductor layer comprise a same material.

9. The method for forming the semiconductor structure as claimed in claim 1, further comprising:
conformally forming a dielectric material on the floating gate and the isolation structures; and
forming a control gate on the dielectric material.

10. The method for forming the semiconductor structure as claimed in claim 9, wherein the dielectric material comprises:
a first dielectric layer;
a second dielectric layer on the first dielectric layer; and
a third dielectric layer on the second dielectric layer.

11. A semiconductor structure, comprising:
a substrate;
a dielectric layer on the substrate;
isolation structures extending through the dielectric layer into the substrate; and
a floating gate on the dielectric layer and between the isolation structures, wherein the floating gate comprises:
a first portion directly on the dielectric layer; and
second portions on sidewalls of the first portion.

12. The semiconductor structure as claimed in claim 11, wherein a width of a top portion of the floating gate is greater than a width of a bottom portion of the floating gate.

13. The semiconductor structure as claimed in claim 11, wherein the floating gate comprises rounded corners.

14. The semiconductor structure as claimed in claim 11, wherein a top surface of the floating gate is higher than top surfaces of the isolation structures.

15. The semiconductor structure as claimed in claim 11, wherein bottom surfaces of the second portions are in direct contact with top surfaces of the isolation structures.

16. The semiconductor structure as claimed in claim 11, wherein the first portion is in direct contact with sidewalls of the isolation structures.

17. The semiconductor structure as claimed in claim 11, wherein the first portion and the second portions comprise a same material.

18. The semiconductor structure as claimed in claim 11, further comprising:
a dielectric material disposed along a sidewall and a top surface of the floating gate and along top surfaces of the isolation structures; and
a control gate on the dielectric material.

19. The semiconductor structure as claimed in claim 18, wherein the dielectric material comprises:
a first dielectric layer;
a second dielectric layer on the first dielectric layer; and
a third dielectric layer on the second dielectric layer.
